(19) United States
(12) Patent Application Publication
(10) Pub. No.: US 2026/0153640 A1
(43) Pub. Date: Jun. 4, 2026

(54) METHODS TO PERFORM NUCLEAR MAGNETIC RESONANCE MEASUREMENTS, AND NUCLEAR MAGNETIC RESONANCE TOOLS

(71) Applicant: Halliburton Energy Services, Inc., Houston, TX (US)

(72) Inventor: Arcady Reiderman, Richmond, TX (US)

(73) Assignee: Halliburton Energy Services, Inc., Houston, TX (US)

(21) Appl. No.: 19/395,783

(22) Filed: Nov. 20, 2025

Related U.S. Application Data
(63) Continuation-in-part of application No. 18/241,176, filed on Aug. 31, 2023.

(51) Int. Cl. G01V 3/32; G01R 33/56; G01V 3/38

(52) U.S. Cl. CPC G01V 3/32; G01R 33/5608; G01V 3/38

(57) ABSTRACT

Methods and systems herein may perform nuclear magnetic resonance measurements, and nuclear magnetic resonance tools, the method and systems comprising: acquiring, using an NMR sensor a first NMR signal from a volume in a subterranean region, wherein the first NMR signal is acquired using a first acquisition window. Further, acquiring, using the NMR sensor a second NMR signal from a volume in the subterranean region, wherein the second NMR signal is acquired using a second acquisition window different from the first acquisition window, wherein the first NMR signal and the second NMR signal form an NMR relaxation data; determining, using the first NMR signal and the second NMR signal, a correction term. Finally, the correction term may be used to acquire a corrected relaxation data set.

### CROSS REFERENCE TO RELATED APPLICATIONS

This application is a continuation in part of U.S. patent application Ser. No. 18/241,176, filed Aug. 31, 2023, which is incorporated by reference herein in their entirety.

### BACKGROUND

In the field of logging (e.g. wireline logging, logging while drilling (LWD) and measurement while drilling (MWD), nuclear magnetic resonance (NMR) tools have been used to explore the subsurface based on the magnetic interactions with subsurface material. Some downhole NMR tools include a magnet assembly that produces a static magnetic field, and a coil assembly that generates radio frequency (RF) control signals and detects magnetic resonance phenomena in the subsurface material. Properties of the subsurface material can be identified from the detected phenomena. The present disclosure relates generally to methods to perform nuclear magnetic resonance (NMR) measurements, and nuclear magnetic resonance tools.

Downhole nuclear magnetic resonance (NMR) sensors sometimes have a relatively small radial extent of the sensitivity area making NMR well logging data sensitive to lateral (radial) motion of the tool. In case of NMR logging while drilling, the lateral motion (vibration) along with rotation may cause severe distortion of the NMR data and even inability to acquire a spin echo signal representing transversal NMR relaxation. While rotational sensitivity may be reduced/eliminated by making an essentially axially symmetrical design of the sensor, the longitudinal and lateral displacement due to tool motion (vibration) remains one of the biggest problems of NMR logging while drilling (LWD)/measurement while drilling (MWD). This is because NMR sensors and components move during lateral motional effects which may distort measurements.

### BRIEF DESCRIPTION OF THE DRAWINGS

Illustrative embodiments of the present disclosure are described in detail below with reference to the attached drawing figures, which are incorporated by reference herein, and wherein:

FIG. 1A is a diagram of an example well system;

FIG. 1B is a diagram of an example well system that includes an NMR tool in a wireline logging environment;

FIG. 1C is a diagram of an example well system that includes an NMR tool in an LWD environment;

FIG. 2 is a diagram of an example downhole tool for obtaining NMR data from a subterranean region;

FIG. 3 is a graph of example waveforms of radio frequency (RF) refocusing pulses applied to a subterranean volume and resulting spin echo signals acquired from the volume;

FIG. 4A shows a first example in which a first acquisition window is used.

FIG. 4B shows a second example 410 in which a second acquisition window is used.

FIG. 4C shows a third example in which a third acquisition window is used.

FIG. 5A is a graph of results of a numerical simulation of the motion effect on the relaxation data acquired with different RF pulses;

FIG. 5B is a graph of a result of the motion effect correction;

FIG. 6A illustrates results of numerical simulation of the motion effect on the relaxation data for the refocusing RF pulse width 50 μs;

FIG. 6B illustrates two datasets curves and selected to calculate the correction term; and

FIG. 6C illustrates the result of the motion effect correction.

FIG. 7A illustrates results of numerical simulation of the motion effect on the relaxation data for 1D lateral displacement of the sensor.

FIG. 7B illustrates two datasets chosen to calculate the correction term.

FIG. 7C illustrates the result of the motion effect correction.

FIG. 8A are results of numerical simulation of the motion effect on the relaxation data for 1D lateral displacement of the sensor.

FIG. 8B shows 2 datasets (curves 804 and 808) chosen to calculate the correction term.

FIG. 8C illustrates the result of the motion effect correction.

FIG. 9A are results of numerical simulation of the motion effect on the relaxation data for 2D lateral displacement (whirling) of the sensor.

FIG. 9B shows 2 datasets (curves 904 and 908) chosen to calculate the correction term. FIG. 9C illustrates the result of the motion effect correction.

FIG. 10 illustrates an example (a result of simulation) of dependence of the correlation coefficient on the auxiliary acquisition window width relative to the main acquisition window width.

FIG. 11 illustrates an example where an acquisition window equals two times the RF pulse width is the best choice.

FIG. 12 illustrates a workflow 1200 to perform nuclear magnetic resonance measurements.

FIG. 13A shows a standard (matched) acquisition.

FIG. 13B illustrates a time shift.

The illustrated figures are only exemplary and are not intended to assert or imply any limitation with regard to the environment, architecture, design, or process in which different embodiments may be implemented.

### DETAILED DESCRIPTION

In the following detailed description of the illustrative embodiments, reference is made to the accompanying drawings that form a part hereof. These embodiments are described in sufficient detail to enable those skilled in the art to practice the invention, and it is understood that other embodiments may be utilized and that logical structural, mechanical, electrical, and chemical changes may be made without departing from the spirit or scope of the invention. To avoid detail not necessary to enable those skilled in the art to practice the embodiments described herein, the description may omit certain information known to those skilled in the art. The following detailed description is, therefore, not to be taken in a limiting sense, and the scope of the illustrative embodiments is defined only by the appended claims.

Methods and systems disclosed herein relate to methods to perform nuclear magnetic resonance measurements, and nuclear magnetic resonance (NMR) tools. In addition, to overcome current problems in the art, methods and systems are configured for reducing the lateral motional effects on NMR relaxation data based on calculation of a relaxation data correction term calculated from CPMG echo train signals acquired with at least two different acquisition windows. The NMR tool includes an acquisition system that is configured to acquire first and second NMR signals from a volume in the subterranean region. For example, an acquired spin echo signal is integrated over an acquisition window (e.g., a time domain filter) to generate a corresponding NMR signal, which includes a relaxation component and, in some cases, a motion component. The first NMR signal is acquired using a first acquisition window having a first duration, while the second NMR signal is acquired using a second acquisition window having a second duration, which is different than the first duration.

Further, methods and systems discussed below overcome additional technical challenges. In examples, a correction term may be calculated based on at least two NMR relaxation datasets differently affected by lateral motion of the tool, the correction term may be used to reduce lateral motion effect on the relaxation data. First dataset has the acquisition window corresponding to matched reception of the NMR echo signal (typically having the window duration substantially equal to the RF pulse width). To reduce noise when calculating the correction term, a data smoothing may be used with the smoothing window chosen based on expected lateral motion frequency spectrum. To further minimize the additional noise introduced to the relaxation data by the motion correction procedure, the two different acquisition windows may be chosen to maximize signal-to-noise ratio (SNR) of the correction term. An additional set of NMR relaxation data acquired with different radio-frequency pulse width/shape may be used to achieve a better accuracy of the relaxation data correction.

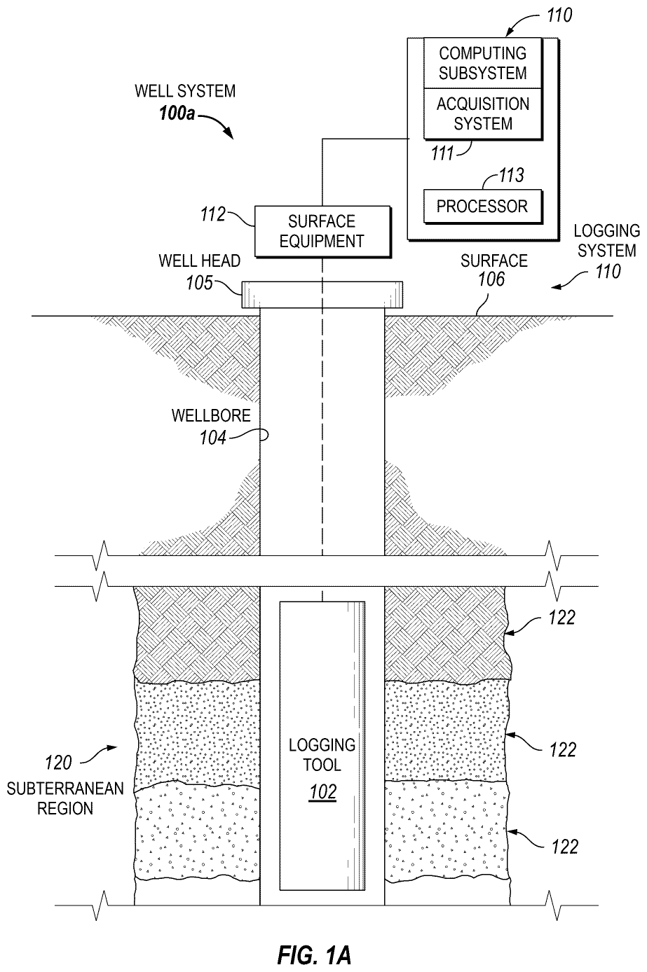

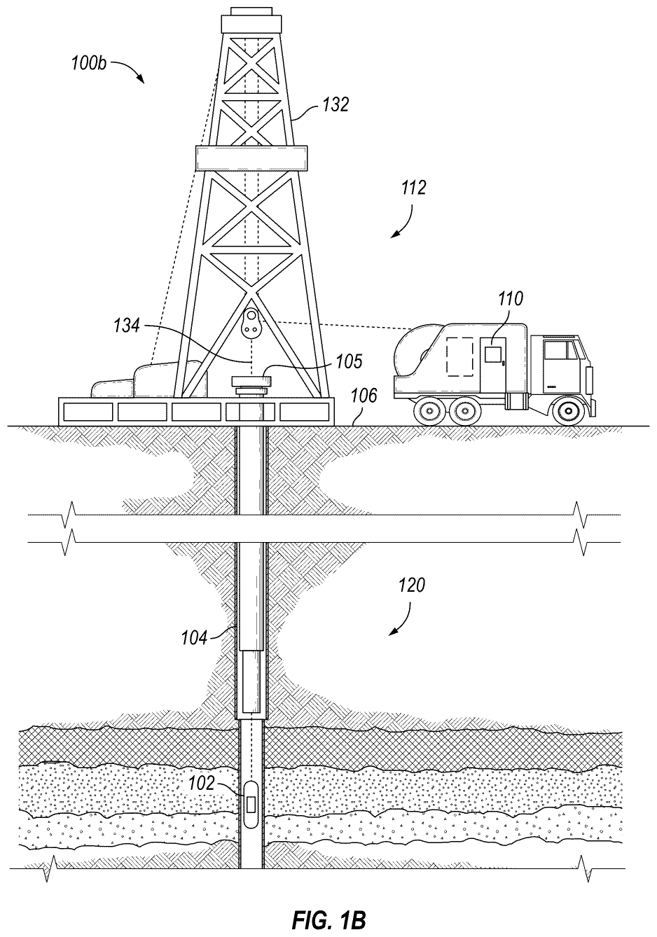

The first NMR signal and the second NMR signal are utilized to determine a motion indicator data, where the motion indicator data is indicative of a lateral motion of the NMR sensor and substantially independent of the intrinsic NMR relaxation parameters of the earth formation in the volume in the subterranean region. Further, a motion multiplier vector is estimated directly from the motion indicator data. The motion multiplier vector is then applied to generate NMR relaxation data with reduced motion effects. Additional descriptions of the foregoing methods to perform nuclear magnetic resonance measurements, and nuclear magnetic resonance tools are described in the paragraphs below and are illustrated in FIGS. 1-7.

FIG. 1A is a diagram of an example well system 100a. The example well system 100a includes an NMR logging system 108 and a subterranean region 120 beneath the ground surface 106. A well system can include additional or different features that are not shown in FIG. 1A. For example, the well system 100a may include additional drilling system components, wireline logging system components, etc.

In some embodiments, subterranean region 120 includes all or part of one or more subterranean formations or zones. The example subterranean region 120 shown in FIG. 1A includes multiple subsurface layers 122 and a wellbore 104 penetrated through the subsurface layers 122. In some embodiments, 1A subsurface layers 122 include sedimentary layers, rock layers, sand layers, or combinations of these and other types of subsurface layers. In some embodiments, one or more of the subsurface layers contain fluids, such as brine, oil, gas, etc. Although the example wellbore 104 shown in FIG. 1A is a vertical wellbore, in some embodiments, the NMR logging system 108 is implemented in other wellbore orientations. For example, the NMR logging system 108 may be adapted for horizontal wellbores, slanted wellbores, curved wellbores, vertical wellbores, or combinations thereof.

The example NMR logging system 108 includes a logging tool 102 (also referred to herein as an NMR tool 102), surface equipment 112, and a computing subsystem 110. In the example shown in FIG. 1A, the logging tool 102 is a downhole logging tool that operates while disposed in the wellbore 104. The example surface equipment 112 shown in FIG. 1A operates at or above the surface 106, such as near the wellhead 105, to control the logging tool 102, and possibly to control other downhole equipment or other components of the well system 100a. The example computing subsystem 110 is configured to receive and analyze logging data from the logging tool 102, such as described below in further detail. For example, the computing subsystem 110 may include at least an acquisition system 111 to acquire or receive data (e.g., from the logging tool 102) and a processor 113 to process the acquired or received data. The NMR logging system 108 may include additional or different features, and the features of the NMR logging system 108 may be arranged and operated as represented in FIG. 1A or in another manner.

In some instances, all or part of the computing subsystem 110 is implemented as a component of or is integrated with one or more components of the surface equipment 112, the logging tool 102 or both. In some cases, the computing subsystem 110 is implemented as one or more computing structures separate from the surface equipment 112 and the logging tool 102.

In some implementations, the computing subsystem 110 is embedded in the logging tool 102, and the computing subsystem 110 and the logging tool 102 are configured to operate concurrently while disposed in the wellbore 104. For example, although the computing subsystem 110 is shown above the surface 106 in the example shown in FIG. 1A, all or part of the computing subsystem 110 may reside below the surface 106, for example, at or near the location of the logging tool 102 or integrated to the logging tool 102.

In some embodiments, well system 100a includes communication or telemetry equipment that enables communication among the computing subsystem 110, the logging tool 102, and other components of the NMR logging system 108. For example, the components of the NMR logging system 108 can each include one or more transceivers or similar apparatus for wired or wireless data communication among the various components. For example, the NMR logging system 108 can include systems and apparatus for optical telemetry, wireline telemetry, wired pipe telemetry, mud pulse telemetry, acoustic telemetry, electromagnetic telemetry, or a combination of these and other types of telemetry. In some cases, the logging tool 102 is configured to receive commands, status signals, or other types of information from the computing subsystem 110 or another source. In some cases, the computing subsystem 110 receives logging data, status signals, or other types of information from the logging tool 102 or another source.

The computing subsystem 110 may include a program memory that is configured to store executable instructions of one or more software programs corresponding to the functions described herein. The program memory may physically reside within computing subsystem 110 or at other computing resources accessible to computing subsystem 110, such as within the local memory resources of other memory devices and storage devices coupled to the computing subsystem 110, or within a server or other network-accessible memory resources accessible by the computing subsystem 110 or distributed among multiple locations. In any case, this program memory constitutes a non-transitory computer-readable medium that stores executable computer program instructions, according to which the operations described in this specification are carried out by computing subsystem 110, or by a server or other computer coupled to computing subsystem 110 (e.g., via network interfaces). The computer-executable software instructions corresponding to software programs to perform the functions described herein may have originally been stored on a removable or other non-volatile computer-readable storage medium (e.g., a DVD disk, flash memory, or the like), or downloadable as encoded information on an electromagnetic carrier signal, in the form of a software package from which the computer-executable software instructions were installed by computing subsystem 110 in the conventional manner for software installation. It is contemplated that those skilled in the art will be readily able to implement the storage and retrieval of the applicable data, program instructions, and other information useful in connection with this embodiment, in a suitable manner for each particular application, without undue experimentation.

In examples of this disclosure, NMR logging operations can be performed in connection with various types of downhole operations at various stages in the lifetime of a well system. Structural attributes and components of the surface equipment 112 and logging tool 102 can be adapted for various types of NMR logging operations. For example, NMR logging may be performed during drilling operations, during wireline logging operations, or in other contexts. Accordingly, the surface equipment 112 and the logging tool 102 may include, or may operate in connection with drilling equipment, wireline logging equipment, or other equipment for other types of operations. As another example, NMR logging may be performed in an offshore or subsea environment. Accordingly, the surface equipment 112 may be arranged on a drill ship or other offshore drilling vessel, and the logging tool 102 operates in connection with offshore drilling equipment, offshore wireline logging equipment, or other equipment for use with offshore operations.

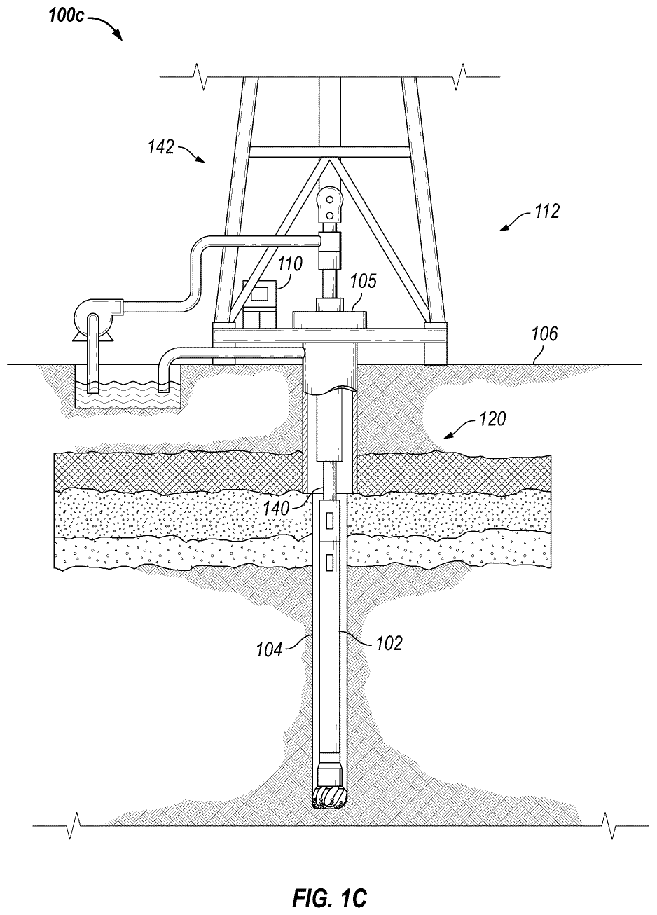

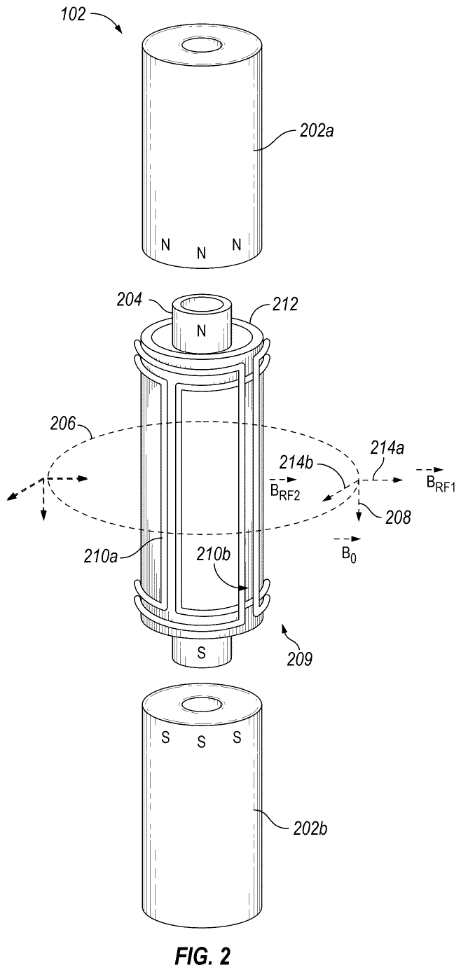

In some implementations, the logging tool 102 includes a magnet assembly that includes a central magnet and two end piece magnets FIG. 2 shows an example of such a configuration, although the specific geometry and/or configuration of the logging tool 102 is not necessarily limited to that shown in FIG. 2. In some examples, the end piece magnets are spaced apart from the axial ends of the central magnet. The end pieces together with the central magnets can define four magnetic poles, which may be arranged to enhance the static magnetic field in a volume of interest (e.g., including one or more of the subsurface layers 122 or portions thereof). The logging tool 102 can also include multiple orthogonal transversal-dipole antennas. The orthogonal transversal-dipole antennas can produce circular polarized excitation in a subterranean volume and acquire a response from the volume by quadrature coil detection.

In some examples, NMR logging operations are performed during wireline logging operations. FIG. 1B shows an example well system 100b that includes the logging tool 102 in a wireline logging environment. In some example wireline logging operations, the surface equipment 112 includes a platform above the surface 106 equipped with a derrick 132 that supports a wireline cable 134 that extends into the wellbore 104. Wireline logging operations can be performed, for example, after a drill string is removed from the wellbore 104, to allow the wireline logging tool 102 to be lowered by wireline or logging cable into the wellbore 104.

In some examples, NMR logging operations are performed during drilling operations. FIG. 1C shows an example well system 100c that includes the logging tool 102 as an NMR tool 102 in a LWD/MWD environment. Drilling is commonly carried out using a string of drill pipes connected together to form a drill string 140 that is lowered through a rotary table into the wellbore 104. In some cases, a drilling rig 142 at the surface 106 supports the drill string 140, as the drill string 140 is operated to drill a wellbore penetrating the subterranean region 120. The drill string 140 may include, for example, a kelly, drill pipe, a bottomhole assembly, and other components. The bottomhole assembly on the drill string may include drill collars, drill bits, the NMR tool 102, and other components, including additional logging tools 102. The additional logging tools 102 may include MWD tools, LWD tools, and others.

In the embodiment of FIG. 1B, the NMR tool 102 can be suspended in the wellbore 104 by a coiled tubing, wireline cable, or another structure that connects the tool to a surface control unit or other components of the surface equipment 112. In some example implementations, the NMR tool 102 is lowered to the bottom of a region of interest and subsequently pulled upward (e.g., at a substantially constant speed) through the region of interest. As shown, for example, in FIG. 1C, the NMR tool 102 can be deployed in the wellbore 104 on jointed drill pipe, hard wired drill pipe, or other deployment hardware. In some example implementations, the NMR tool 102 collects data during drilling operations as it moves downward through the region of interest. In some example implementations, the NMR tool 102 collects data while the drill string 140 is moving, for example, while it is being tripped in or tripped out of the wellbore 104.

As explained herein, NMR well logging data are sensitive to lateral (e.g., radial) motion of the NMR tool 102. In an example in which the NMR tool 102 is used in a LWD or MWD context such as in FIG. 1C, the lateral motion (e.g., vibration) and rotational movement of drilling operations may cause distortion of the NMR well logging data (e.g., due to the introduction of a motion component to the acquired NMR signal(s)) and, in some cases, an inability to acquire a spin echo signal representing transversal NMR relaxation, without such motion components. While rotational sensitivity may be reduced by designing the NMR tool 102 to be essentially axially symmetrical (e.g., as shown in FIG. 2), the longitudinal and lateral displacement due to motion of the NMR tool 102 (e.g., vibration), such as while drilling, remains problematic for NMR data acquisition in a LWD or MWD context.

As described herein, the acquisition system 111 of the computing subsystem 110 acquires first and second NMR signals from a volume in the subterranean region 120. The first NMR signal is acquired using a first acquisition window having a first duration, while the second NMR signal is acquired using a second acquisition window having a second duration, which is different than the first duration. Motion effects on the NMR tool 102 are observable by comparing NMR signals acquired using acquisition windows having different durations. In some examples, the NMR signals acquired using acquisition windows having different durations are first normalized before being compared. Accordingly, the processor 113 is configured to determine the motion effects (e.g., lateral displacement of the NMR tool 102 as a function of time) based on the first and second NMR signals from the acquisition system 111. In an example, the processor 113 is also configured to generate NMR relaxation data with reduced motion effects, such as by applying the determined lateral displacement to one of the acquired NMR signals using numerical simulation.

In some implementations, the NMR tool 102 collects data at discrete logging points in the wellbore 104. For example, the NMR tool 102 can move upward or downward incrementally to each logging point at a series of depths in the wellbore 104. At each logging point, instruments in the NMR tool 102 perform measurements on the subterranean region 120. The measurement data can be communicated to the computing subsystem 110 for storage, processing, and analysis. Such data may be gathered and analyzed during drilling operations (e.g., during LWD operations), during wireline logging operations, or during other types of activities.

The computing subsystem 110 is configured to receive and analyze the measurement data from the NMR tool 102 to detect properties of various subsurface layers 122. In some implementations, the NMR tool 102 obtains NMR signals by polarizing nuclear spins in the subterranean region 120 and pulsing the nuclei with a radio frequency (RF) magnetic field. Various pulse sequences (i.e., series of radio frequency pulses, delays, and other operations) can be used to obtain NMR signals, including the CPMG sequence (in which the spins are first tipped using a tipping pulse followed by a series of refocusing pulses), the Optimized Refocusing Pulse Sequence (ORPS) (in which the refocusing pulses are less than 180°), a saturation recovery pulse sequence, and other pulse sequences.

The computing subsystem 110 is configured to process (e.g., invert, transform, etc.) the acquired spin echo signals (or other NMR data) to obtain an NMR signal, such as a relaxation-time distribution (e.g., a distribution of transverse relaxation times T2, or a distribution of longitudinal relaxation times T1, or both). For example, the acquired spin echo signals are integrated using acquisition windows having different durations to generate the different NMR signals, described above. The relaxation-time distribution can be used to determine various physical properties of the formation by solving one or more inverse problems. In some cases, relaxation-time distributions are acquired for multiple logging points and used by the computing subsystem 110 to train a model of the subterranean region. In some cases, relaxation-time distributions are acquired for multiple logging points and used by the computing subsystem 110 to predict properties of the subterranean region.

FIG. 2 is a diagram of an example of the NMR tool 102, described above. The example NMR tool 102 includes a magnet assembly that generates a static magnetic field to produce polarization, and an antenna assembly that generates a radio frequency (RF) magnetic field to excite nuclei and acquires NMR signals from the surrounding formation. In the example shown in FIG. 2, the magnet assembly that includes the end piece magnets 202a, 202b and a central magnet 204 generates the static magnetic field in the volume of investigation 206. The poles of the central magnet 204 (e.g., north (N) and south(S)) face the like poles of the proximal end piece magnets 202a, 202b. The central magnet 204 is useful to shape and strengthen the static magnetic field in the volume of investigation 206. In this example, the volume of investigation 206 is approximately a cylindrical shell. In the volume of investigation 206, the direction of the static magnetic field (shown as the solid black arrow 208) is parallel to the longitudinal axis of the wellbore 104. In some examples, a magnet configuration with double pole strength can be used to increase the strength of the magnetic field (e.g., up to 100-150 Gauss or higher in some instances).

In the example shown in FIG. 2, the antenna assembly 209 includes two mutually orthogonal transversal dipole antennas 210a, 210b. In some instances, the NMR tool 102 can be implemented with a single transversal-dipole antenna. For example, one of the transversal-dipole antennas 210a, 210b may be omitted from the antenna assembly 209. The example transversal-dipole antenna 210a, 210b shown in FIG. 2 are placed on an outer surface of a soft magnetic core 212, which is useful for RF magnetic flux concentration. The antenna assembly 209 generates two orthogonal RF magnetic fields 214a (e.g., produced by the antenna 210a) and 214b (e.g., produced by the antenna 210b). The two RF magnetic fields 214a, 214b have a phase shift of 90°. Accordingly, the magnetic fields 214a, 214b generate a circular polarized RF magnetic field to provide NMR signals to the surrounding formation more efficiently. The same two antennas 210a, 210b are used to receive NMR signals from the surrounding formation. The received NMR signals induce corresponding signals in the orthogonal antennas 210a, 210b, which may then be processed (e.g., by the computing subsystem 110) in order to increase a signal-to-noise ratio (SNR) of the acquired NMR data as described further below.

The static magnetic field can be axially symmetric (or substantially axially symmetric) and therefore may not require broader band excitation associated with additional energy loss. The volume of investigation can be made axially long enough and thick enough (e.g., 15 cm long, and 1 cm thick) to provide immunity or otherwise decrease sensitivity to axial motion, lateral motion, or both. A longer sensitivity region can enable measurement while tripping the drill string 140. The sensitivity region can be shaped by shaping the magnets 202a, 202b, 204 and the soft magnetic material of the core 212.

In some implementations, the antenna assembly 209 additionally or alternatively includes an integrated coil set that performs the operations of the two transversal-dipole antennas 210a, 210b. For example, the integrated coil may be useful (e.g., instead of the two transversal-dipole antennas 210a, 210b) to produce circular polarization and perform quadrature coil detection. Examples of integrated coil sets that can be adapted to perform such operations include multi-coil or complex single-coil arrangements, such as, for example, birdcage coils used for high-field magnetic resonance imaging (MRI).

Compared to some example axially-symmetrical designs, the use of the longitudinal-dipole magnet and the transversal-dipole antenna assembly also has an advantage of less eddy current losses in the formation and drilling fluid (i.e., “mud”) in the wellbore 104 due to a longer eddy current path than for some longitudinal-dipole antenna(s).

In some aspects, NMR measurements over multiple sub-volumes can increase the data density and therefore SNR per unit time. Multiple volume measurements in a static magnetic field having a radial gradient can be achieved, for example, by acquiring NMR data on a second frequency while waiting for nuclear magnetization to recover (e.g., after a CPMG pulse train) on a first frequency. A number of different frequencies can be used to run a multi-frequency NMR acquisition involving a number of excitation volumes with a different depth of investigation. In addition to higher SNR, the multi-frequency measurements can also enable profiling the fluid invasion in the wellbore, enabling a better assessment of permeability of earth formations. Another way to conduct multi-volume measurements is to use different regions of the magnet assembly to acquire an NMR signal. NMR measurements of these different regions can be run at the same time (e.g., simultaneously) or at different times.

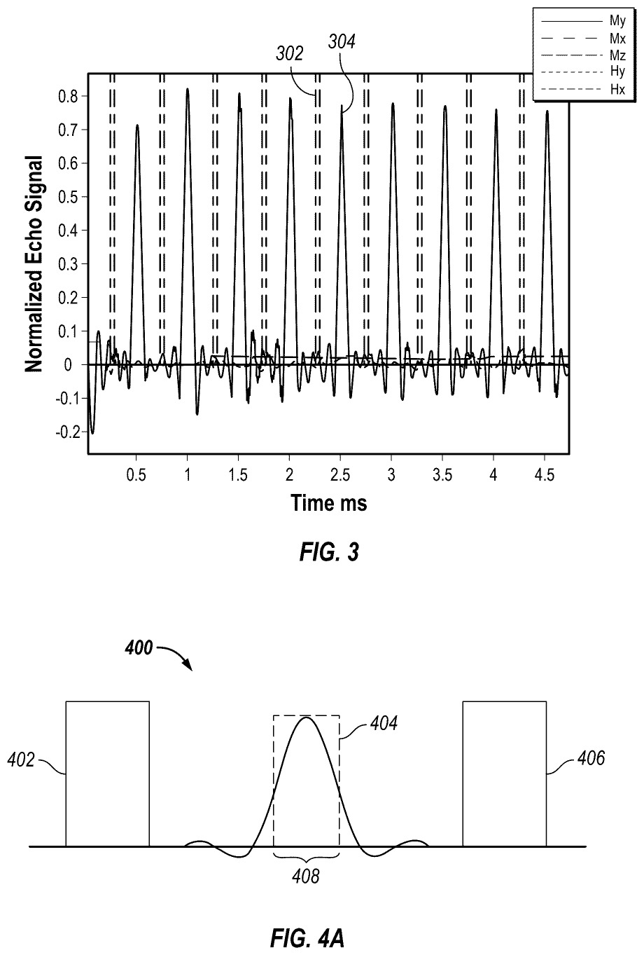

FIG. 3 is a graph of example waveforms of radio frequency (RF) pulses, which are demonstrated as envelopes of RF pulses notated 302, applied to a subterranean volume, such as the subterranean region 120. The graph also includes resulting main, in-phase components of spin echo signals, notated 304, acquired from the volume. The spin echo signals 304 may be acquired from the volume by the NMR tool 102, such as by the antennas 210a, 210b. The graph also includes an out-of-phase component of the spin echo signals, and a longitudinal component of the spin echo signals. The RF refocusing pulses represented by envelopes 302 and the resulting, acquired spin echo signals (e.g., the main, in-phase components 304) are shown as normalized (e.g., to a value of 1.0) magnitudes as a function of time. In the example of FIG. 3, the acquired spin echo signals 304 occur between the RF refocusing pulses 302.

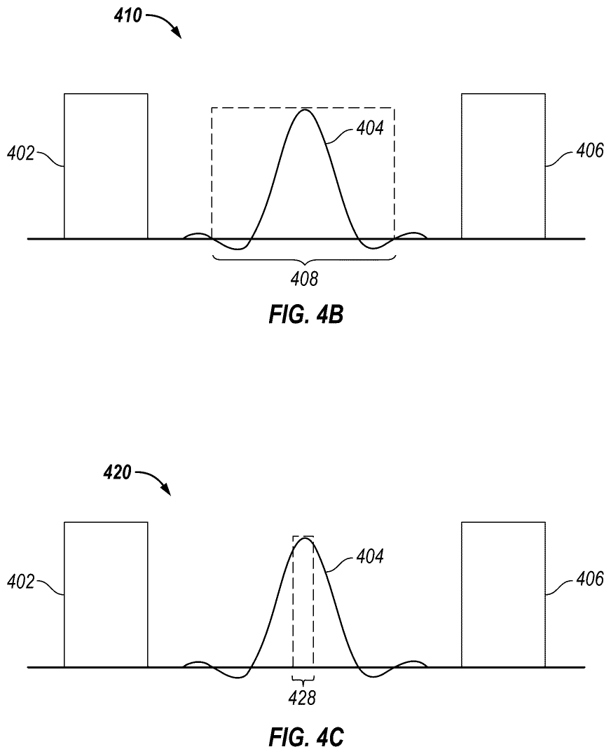

FIGS. 4A-4C show examples of different acquisition windows for a single spin echo between RF refocusing pulses. Each FIGS. 4A-4C includes a first RF refocusing pulse 402, a resulting spin echo 404, and a second or subsequent RF refocusing pulse 406. FIG. 4A shows a first example 400 in which a first acquisition window 408 is used. FIG. 4B shows a second example 410 in which a second acquisition window 418 is used. FIG. 4C shows a third example 420 in which a third acquisition window 428 is used. The acquisition windows 408, 418, 428 correspond to time domain filters over which the spin echo signal 404 is integrated. The result of such integration is an NMR signal, which may include a relaxation component and a motion component in some examples.

In the first example 400, the first acquisition window 408 has a duration that corresponds to a substantially matched reception and normally used for acquisition, and is selected to improve or maximize SNR of the spin echo 404. In the second example 410, the second acquisition window 418 is the wider window (narrow-band reception in the frequency domain terms), and has a duration that is greater than the duration of the first acquisition window 408, and thus corresponds to a narrower-band reception in the frequency domain. In the third example 420, the third acquisition window 428 has a duration that is less than the duration of the first acquisition window 408, and thus corresponds to a wider-band reception in the frequency domain. In some cases, the second and third acquisition windows 418, 428 result in inferior SNR of the spin echo 404 relative to the first acquisition window 408. However, the third, shorter acquisition window 428 in particular may be useful to reduce the time between RF refocusing pulses 402, 406, and correspondingly the time-to-echo (TE). In some cases, a smaller TE may be useful when the NMR signal includes relatively short relaxation components to be acquired. As explained herein, NMR signals (e.g., processed spin echoes) acquired or generated using different acquisition window durations, which correspond to different reception bandwidths, have different sensitivities to motion effects, or lateral displacement, of the NMR tool 102. In that regard, techniques described herein are based on the assumption that the echo data acquired with different acquisition windows (different reception bandwidth) have different sensitivity to the lateral motion. More particularly, different widths and shapes of the acquisition windows (or frequency responses of filters in frequency domain) are used to increase relative sensitivity to lateral motion and therefore used to produce a motion indicator based on NMR relaxation data.

In some embodiments, the relaxation data set R(t, W) acquired from NMR tool 102, as described above, is presented as the following equation:

$$\begin{matrix}R ( t , W ) = MM ( t , W ) \cdot {R}_{0} ( t , W ) & t = {t}_{j} ( echo points )\end{matrix} \qquad Equation ( 1 )$$

where MM(t, W) is the motion multiplier vector (motion multiplier) reflecting lateral motion effect on the acquired relaxation data, the multiplier dependent on the acquisition window W, and R₀ (t, W) is the relaxation data unaffected by the lateral motion (intrinsic relaxation data), t is the time at a particular point on the R(t) or MM (t) curves. Each point on these curves corresponds to a particular tⱼ, spin echo (an echo point). The motion multiplier may be presented by the following equation:

$$MM ( t , W ) = 1 - δ [ W , d ( t ) ] , max ( \vert δ ( t ) \vert ) ≪ 1 \qquad Equation ( 2 )$$

where δ[W, d(t)] is the motion related error, which is a function of a time dependent lateral displacement d(t) of the sensor.

In the presence of lateral motion, both MM and R₀ are unknown. To remove the motion induced distortion of the NMR relaxation data the motion multiplier MM may be estimated. Having at least two relaxation data sets with different excitation or/and reception parameters (e.g., different acquisition windows) and differently affected by the motion allows for calculation of a motion indicator MI that may be defined by the following equation:

$$MI ( t , {W}_{0} , {W}_{M} ) = \frac{{R}_{ns} ( t , {W}_{M} )}{{R}_{ns} ( t , {W}_{0} )} - 1 , \qquad Equation ( 3 )$$

where Rₙₛ represents normalized smoothed relaxation data as a function of time and the acquisition window width, W₀, and W_{M} are the different acquisition window widths for two sets of relaxation data.

In some embodiments, the window width W₀ preferably corresponds to maximum signal-to-noise ratio (matched reception) and considered the main window while Way is an auxiliary window used to reduce lateral motion effect on the main set of data.

As follows from Equation (1) and Equation (3), the MI substantially does not depend on the intrinsic relaxation and is only affected by the lateral motion. In examples, the relationship between motion related errors for different acquisition windows make take the following form:

$$δ [ {W}_{M} , d ( t ) ] = F \{ δ [ {W}_{0} , d ( t ) ] \} , \qquad Equation ( 4 a )$$

where F denotes a function that transforms the motion related error for the acquisition window W₀ into the motion error for the acquisition window W_{M}.

In some embodiments, the function depends on W₀, W_{M}, and parameters of the RF pulse sequence (e.g., RF pulse width, shape, repetition rate (TE)) while it substantially does not depend on the displacement patterns d (t). In a simple case the function/may take the following linear form:

$$δ [ {W}_{M} , d ( t ) ] \approx a \cdot δ [ {W}_{0} , d ( t ) ] , \qquad Equation ( 4 b )$$

where α is a constant parameter depending only on the acquisition parameters. Then the motion multiplier estimate, MMₑₛₜ (t, W₀) may be calculated as:

$${MM}_{est} ( t , {W}_{0} ) = \frac{1 - a}{1 - a + MI ( t , {W}_{0} , {W}_{M} )} , \qquad Equation ( 5 )$$

and used to correct the relaxation data in order to reduce the motional effect on the NMR relaxation data. The corrected relaxation data set R_{corr} (t) may be calculated by the following equation:

$${R}_{corr} ( t ) = \frac{R ( t , {W}_{0} )}{{MM}_{est} ( t , {W}_{0} )} = [ 1 + c \cdot MI ( t ) ] \cdot R ( t , {W}_{0} ) , \\ with c = \frac{1}{1 - a} \qquad Equation ( 6 )$$

In some embodiments, different RF pulse width and corresponding different acquisition windows (matched reception as shown in FIG. 4A) are used to obtain the motion indicator MI. The motion indicator MI and therefore the motion multiplier MM (motion correction vector) may be calculated for each individual echo-train of the NMR sequence. The corrected relaxation data may be then averaged over a plurality of echo-trains used for the data stacking.

Calculating MI according to equation (3) involves division with noisy denominator. In case the time interval where the MI is calculated includes full relaxation with the relaxation signal dropping to the noise level and below, the result of calculation may be very noisy (even after smoothing the dataset to be used for the calculation). Equations (7) and (8) represent different way of calculating corrected relaxation data. The motion indicator MI may be presented as shown by:

$$MI ( t , {W}_{0} , {W}_{M} ) = \frac{{[ {R}_{na} ( t , {W}_{M} ) - R ( t , {W}_{0} ) ]}_{s}}{{R}_{ns} ( t , {W}_{0} )} , \qquad Equation ( 7 )$$

where Rₙₐ (t, W_{M}) is the normalized relaxation data (to be expressed in the same units as R(t, W₀)) acquired with auxiliary acquisition window (W_{M}) and the term [Rₙₐ (t, W_{M})−R (t, W₀)]ₛ represents the smoothed difference of the two sets of the relaxation data. Then the corrected relaxation data set, R_{corr} (t) may be calculated as follows:

$${R}_{corr} ( t ) = R ( t , {W}_{0} ) + c \cdot {[ {R}_{na} ( t , {W}_{M} ) - R ( t , {W}_{0} ) ]}_{s} , \qquad Equation ( 8 )$$

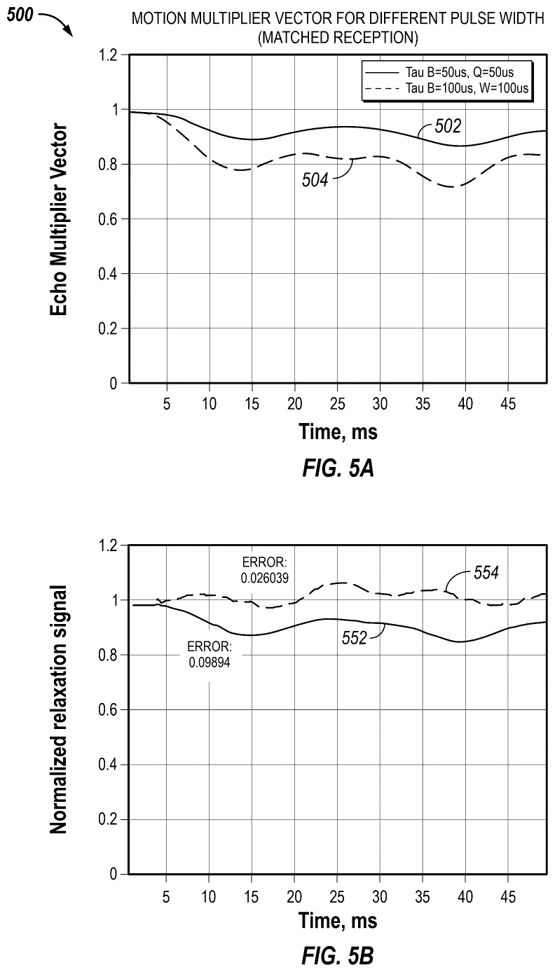

The second term on the right side of the equation (8) is the correction term; its calculation does not involve division with noisy denominator. The corrected data acquired according to equation (8) may be considered approximately the same as that of equation (6). Transferring from (6) to (8) essentially neglects the difference between original and smoothed relaxation datasets acquired with acquisition window W₀ when calculating the correction term. In examples, the correction term may be small relative to the main relaxation term. In an assumption that the lateral motion related error 8 is small (equation (2)) the MI as a function of δ may be linearized and the procedure of calculating the MI, MM and the correction term (in equation (8)) can be applied to the stacked data in order to obtain the stacked corrected data. FIGS. 5A-9C below represent results of numerical simulations of the lateral motion effect on the NMR relaxation. Since relative effect of the lateral motion is substantially independent of the intrinsic relaxation the relaxation spectrum for the simulation was chosen single exponential with T2=10 s. The TE parameter of the pulse sequence was equal to 0.5 ms. The static magnetic field gradient of the sensor was chosen to provide the radial extent of the effective NMR excitation volume equal to 0.5″ for the RF pulse width 50 μs. In one embodiment of the proposed technique different RF pulse width and corresponding different acquisition windows (matched reception as shown in FIG. 4A) are used to obtain the motion indicator MI.

FIG. 5A is a graph 500 of results of a numerical simulation of the motion effect on the relaxation data for the RF pulse width 50 μs (shown at line 502) and 100 μs (shown at line 504). In the embodiment of FIG. 5A, acquisition windows for the RF pulses 50 μs and 100 μs were selected to be 50 μs and 100 μs respectively (matched reception). The simulation was performed for the NMR sensor having a 0.5″ radial extent of the sensitivity volume and for the following lateral displacement of the sensor:

$$d ( t ) = A \cdot [ 1 - cos ( 2 π {f}_{v} \cdot t ) ] , \qquad Equation ( 9 )$$

where A and fᵥ are respectively the amplitude and the frequency of the lateral motion. For the simulation the amplitude was 1/16″ and the frequency was 40 Hz. The intrinsic T2 relaxation used for the numerical was 1 s.

FIG. 5B illustrates the result of the motion effect correction. Shown on FIG. 4B are the simulated (synthetic) relaxation data 552 corresponding to the motion and system parameters specified above, the estimated (using equation (5)) motion multiplier to be used for the relaxation data correction and the corrected data 554. Also shown on FIG. 5B are the RMS (root mean square) motion error for the synthetic data before (Error=0.09894) and after (ErrorCorr=0.026039) correction demonstrating more than 3 times error reduction. The constant parameter α(W₀, W_{M}) was set to be equal to 2.25. It may be shown that substantially the same parameter may be used to reduce motion error for arbitrary motion patterns d (t).

In some embodiments, employing sets of relaxation data with different RF pulse width to correct for motion effect assumes that the motion patterns are substantially unchanged when acquiring data with different RF pulses. In one or more of such embodiments, if the NMR trains with different RF pules are run sequentially/separately in time, the foregoing assumption is true when the motion is a steady (during NMR sequence) whirling or, to some extent, a steady lateral vibration. Also, the trains with different RF pulses may be run simultaneously using, for example, two-frequency operated system with a double-tuned antenna or using interleaving in time pulse trains that are run at different frequencies.

In some embodiments, simultaneously occurred two (or more) sets of data that are differently affected by lateral motion are acquired by using different acquisition windows for the same echo train data (in other words, each relaxation data set acquired with its own filter in receiver channel). NMR spin-echo signal acquired with different acquisition windows differently affected by the lateral motion and therefore potentially permits for the motion effect correction based on the motion indicator as explained herein.

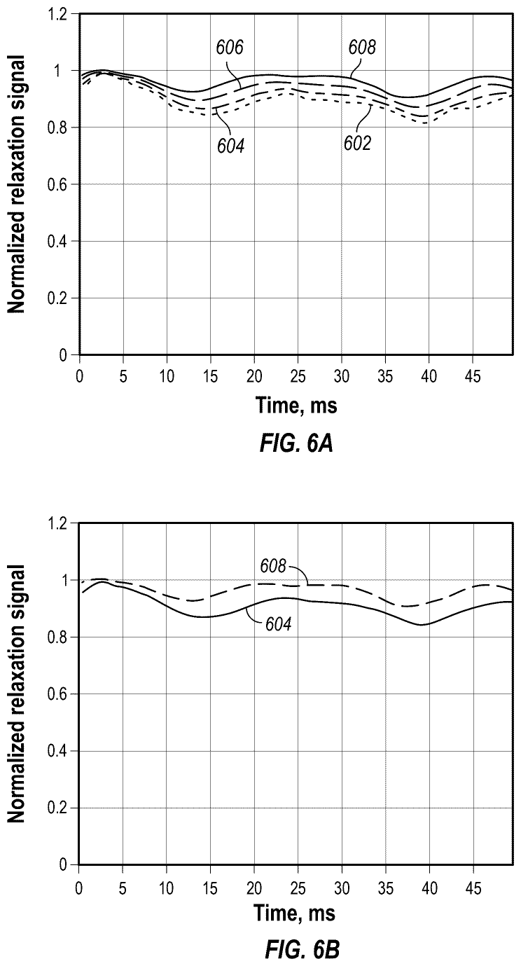

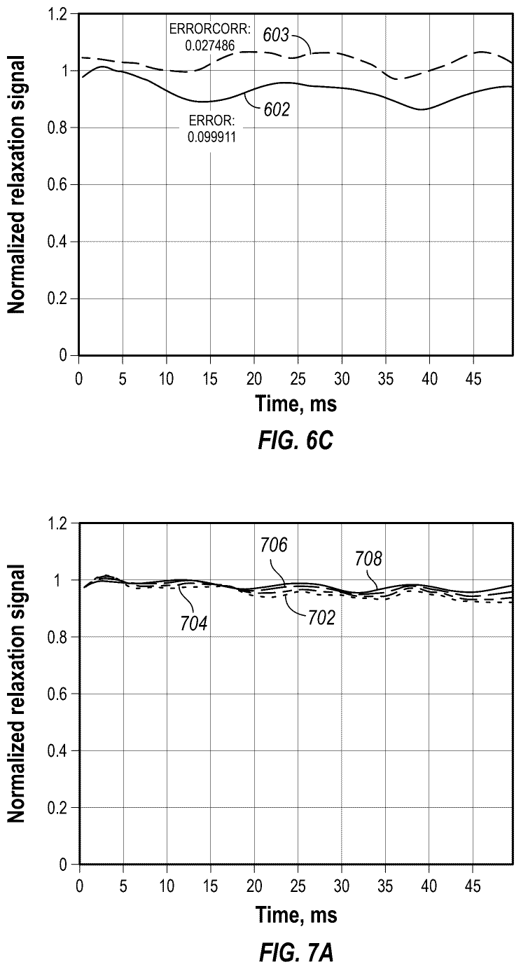

FIG. 6A illustrates results of numerical simulation of the motion effect on the relaxation data for the refocusing RF pulse width 50 μs. The curves 602, 604, 606, and 608 correspond to the acquisition window 25 μs, 50 μs, 75 μs and 100 μs respectively. The simulation was performed for the lateral displacement of the sensor described by the equation (9). FIG. 6B illustrates two datasets curves 608 and 604 selected to calculate the correction term. FIG. 6C illustrates the result of the motion effect correction. The simulated (synthetic) relaxation data curve 602 corresponding to the motion and system parameters specified above and the corrected data curve 606. Also shown on are the RMS (root mean square) motion error for the synthetic data before (Error=0.099911) and after (ErrorCorr=0.027486) correction demonstrating about 4 times error reduction. The parameter α(W₀, W_{M}) was selected to be equal to 0.5, correspondingly c=2. The substantially same parameter c may be used to reduce motion error for different motion patterns (d (t)).

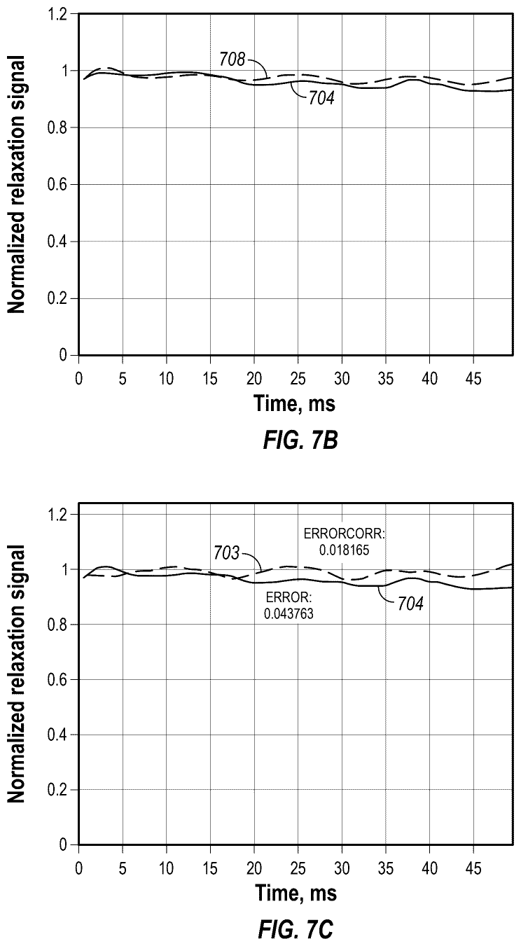

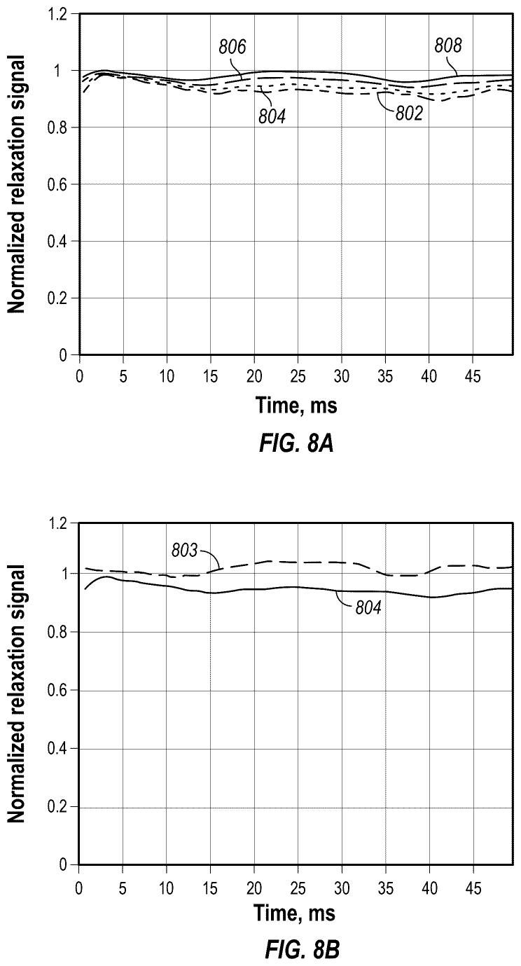

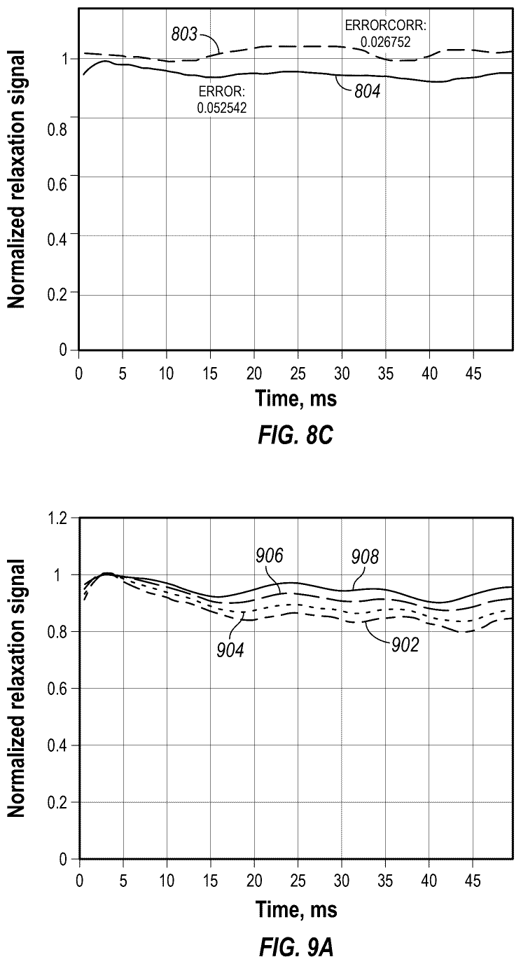

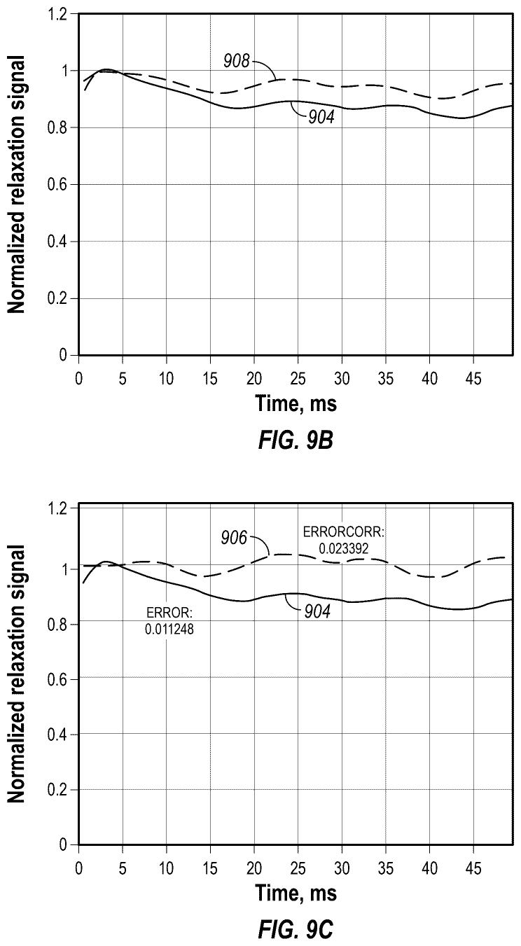

Illustrated in FIG. 7A-C, FIG. 8A-C and FIG. 9A-C are the simulated data and the results of motion correction for different motion regimes. In all cases below the parameter c is the same as in case represented by the FIGS. 5A-C: c=2 (a=0.5). FIG. 7A illustrates results of numerical simulation of the motion effect on the relaxation data for 1D lateral displacement of the sensor described by the equation (10) (90 deg. phase shift relative to that of equation (9)), the RF pulse width 50 μs and acquisition windows 25 μs, 50 μs, 75 μs and 100 μs (curves 702, 704, 706, and 708 respectively). Equation (10) is:

$$d ( t ) = A \cdot [ 1 - sin ( 2 π {f}_{v} \cdot t ) ] , \qquad Equation ( 10 )$$

with fᵥ=40 Hz and A= 1/16″.

FIG. 7B illustrates two datasets (curves 704 and 708) chosen to calculate the correction term. FIG. 7C illustrates the result of the motion effect correction. Shown on FIG. 7C are the simulated (synthetic) relaxation data (curve 704) corresponding to the motion and system parameters specified above and the corrected data (curve 703). Also shown on FIG. 7C are the RMS (root mean square) motion error for the synthetic data before (Error=0.043793) and after (ErrorCorr=0.018165) correction demonstrating more than 2 times error reduction.

Shown on FIG. 8A are results of numerical simulation of the motion effect on the relaxation data for 1D lateral displacement of the sensor described by the equation (9) with A= 1/24″, the RF pulse width 50 μs and acquisition windows 25 μs, 50 μs, 75 μs and 100 μs (curves 802, 804, 806, 808 respectively). FIG. 8B shows 2 datasets (curves 804 and 808) chosen to calculate the correction term. FIG. 8C illustrates the result of the motion effect correction. Shown on FIG. 8C are the simulated (synthetic) relaxation data (curve 804) corresponding to the motion and system parameters specified above and the corrected data (curve 806). Also shown on FIG. 8C are the RMS (root mean square) motion error for the synthetic data before (Error=0.052542) and after (ErrorCorr=0.026752) correction demonstrating about 2 times error reduction.

Shown on FIG. 9A are results of numerical simulation of the motion effect on the relaxation data for 2D lateral displacement (whirling) of the sensor described by the Equation (11), as illustrated below, the RF pulse width 50 μs and acquisition windows 25 μs, 50 μs, 75 μs and 100 μs (curves 902, 904, 906, and 908 respectively). FIG. 9B shows 2 datasets (curves 904 and 908) chosen to calculate the correction term. FIG. 9C illustrates the result of the motion effect correction. Shown on FIG. 9C are the simulated (synthetic) relaxation data (curve 904) corresponding to the motion and system parameters specified above and the corrected data (curve 906). Also shown on FIG. 9C are the RMS (root mean square) motion error for the synthetic data before (Error=0.11248) and after (ErrorCorr=0.023392) correction demonstrating more than 4 times error reduction.

$$\{ \begin{matrix}d ( t ) = A \cdot [ 1 - cos ( 2 π {f}_{v} \cdot t ) ] \\ {d}_{y} ( t ) = A \cdot sin ( 2 π {f}_{v} \cdot t )\end{matrix} , \qquad Equation ( 11 )$$

with fᵥ=40 Hz and A= 1/16″.

By using the correction term as shown in equation (8), it is important to minimize an additional noise introduced by the correction term. The d(t) variation period (e.g., defined by the frequency fv in equation (9)) is typically much larger than the relaxation sampling rate (equal to TE, a parameter of the NMR sequence). This allows for a significant relaxation data smoothing (e.g., by calculating a running average) in order to further reduce the noise of the corrected term (increase the signal-to-noise ratio (SNR) of the correction term).

The additional noise is represented by the second term of the right side of Equation (12):

$${N}_{corr} ( t ) = {N}_{O} ( t ) + c \cdot [ {N}_{Ms} ( t ) - {N}_{0 s} ( t ) ] , \qquad Equation ( 12 )$$

where N_{corr} is the noise of corrected NMR relaxation data, No is the noise of the data to be corrected for motion effect, N_{Ms} (t) and N₀ₛ (t) are the noise data of the two NMR relaxation datasets used to calculate the correction term. For each data point the noises N_{Ms} and N₀ₛ may be acquired from the same echo waveforms with different acquisition (integration) windows and therefore correlated. The correlation level affects total noise level of the of the second term of the Equation (12). In examples, the noise of corrected NMR relaxation data is a further correction of noise from the corrected relaxation data set, R_{corr} (t).

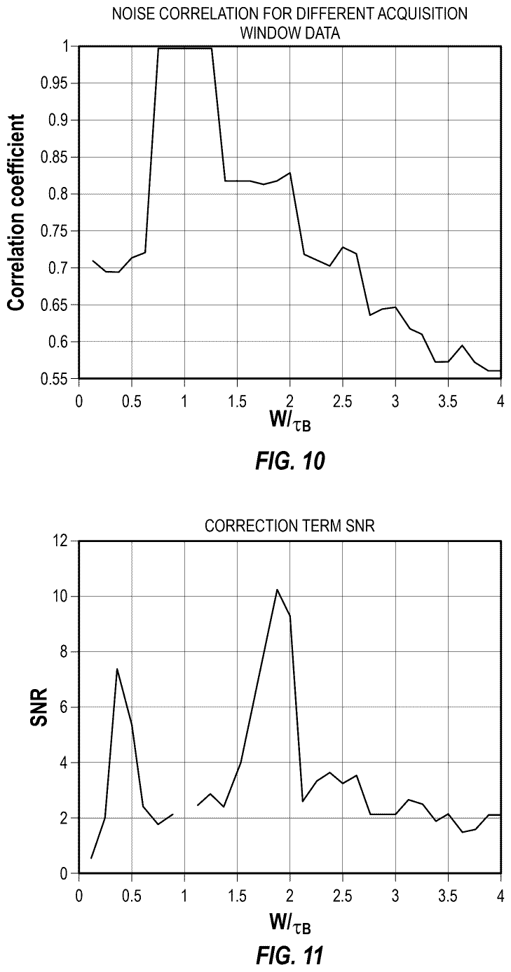

FIG. 10 illustrates an example (a result of simulation) of dependence of the correlation coefficient on the auxiliary acquisition window width relative to the main acquisition window width (equal to the refocusing RF pulse width). This shows Noise Correlation for Different Acquisition Window Data. The dependence shows that the closer the auxiliary acquisition window width to the main window width the closer the coefficient correlation is to 1, and therefore, the smaller the total noise of the correction term. However, as shown on FIGS. 6A, 7A, 8A and 9A, the difference between the normalized NMR relaxation data sets also becomes smaller. Optimum choice of the acquisition window can be made based on the signal-to-noise ratio (SNR) calculated In Equation (13) as:

$${CT}_{SNR} = \frac{{\vert {[ {R}_{na} ( t , {W}_{M} ) - R ( t , {W}_{0} ) ]}_{s} \vert}_{max}}{STD [ {N}_{Ms} ( t ) - {N}_{0 s} ( t ) ]} , \qquad Equation ( 13 )$$

FIG. 11 illustrates an example where an acquisition window equals two times the RF pulse width is the best choice. The NMR relaxation data correction as described above can be done in real time and the corrected data may be sent up hole and analyzed while drilling the well.

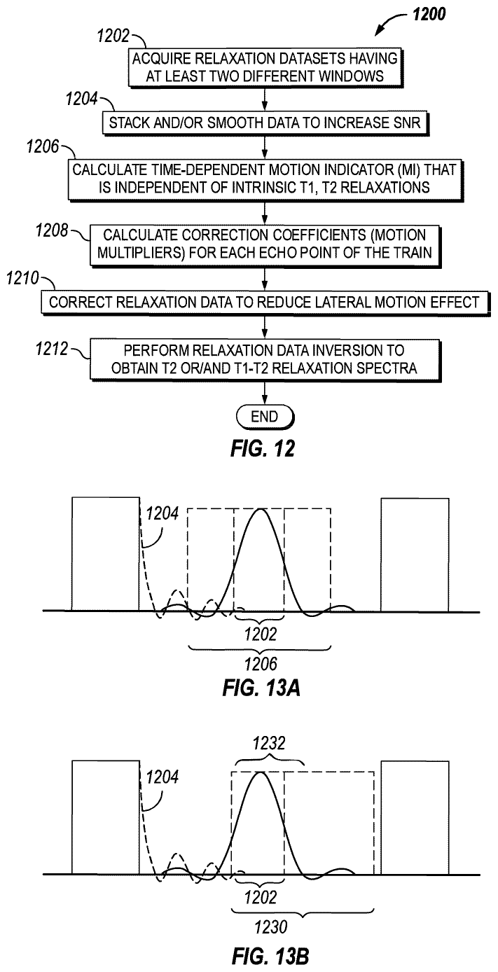

FIG. 12 illustrates a workflow 1200 to perform nuclear magnetic resonance measurements. Although the operations in process 1200 are shown in a particular sequence, certain operations may be performed in different sequences or at the same time where feasible. At block 1202, at least two acquisition windows having different durations or/and shapes (time domain filtering) are acquired and utilized. In some embodiments, the echo signals acquisition is performed using at least two different filters in frequency domain. In some embodiments, d (t) variation period (e.g., defined by the frequency fᵥ in equation (7)) is typically much larger than the relaxation sampling rate (equal to TE, a parameter of the NMR sequence). The foregoing permits for a significant relaxation data smoothing (e.g., by calculating a running average) in order to increase the NMR signal-to-noise ratio when calculating the motion indicator (MI). In other examples, the echo signals acquisition may be performed using at least two different filters in frequency domain. In that regard, at block 1204, data smoothing and/or stacking is performed to increase the signal-to-noise ratio.

At block 1206, a time-dependent motion indicator (MI) that is independent of intrinsic T1 and T2 relaxations are calculated. In one or more or such embodiments, the motion indicator is defined as shown by equation (3). At block 1208, correction coefficients (motion multipliers) are calculated for each echo point of the train. In some embodiments, a vector of the motion multipliers is calculated based on equation (5). At block 1210, the relaxation data is calculated to reduce the lateral motion effect. In some embodiments, the relaxation data is corrected as presented by equation (6). At block 1212, relaxation data inversion is performed to obtain T2 and/or T1-T2 NMR relaxation spectra. In some embodiments, the corrected data is then used to perform the relaxation data inversion to obtain T2 or/and T1-T2 NMR relaxation spectra using standard relaxation data inversion algorithms.

The correction term signal-to-noise ratio CT_{SNR}, calculated according to equation (13), may be also used to assess significance of the lateral motion artifacts. Based on the level of this parameter, a decision whether or not the correction is needed can be made.

Another embodiment of the disclosed method uses a shifted acquisition window as shown in FIG. 13. FIG. 13A shows a standard (matched) acquisition window 1302 and a symmetrical (with respect to the center of the echo signal) longer window 1306. It also shows an undesired electric signal (so called ringing) 1304 that is typically present after the RF pulse. The duration of this signal determines minimum time interval between RF pulses and, correspondingly, minimum time interval (TE) between two consecutive echoes (also the time when the first echo in the CPMG echo train occurs). Reducing minimum achievable TE improves relaxation spectra resolution and increases signal-to-noise ratio (SNR). To integrate echo signal over longer acquisition window when minimum achievable TE for the matched window is used, a shifted window is employed shown at 1330 (the shift from the center of the echo signal is shown at 1332). FIG. 13B illustrates a time shift. The time shift is preferably chosen in a way that sets the beginning of the window at the same position as the beginning of the matched window as shown in FIG. 13B. The longer acquisition window may extend substantially to the start of the next RF pulse.

Statement 1, A method to perform nuclear magnetic resonance measurements, and nuclear magnetic resonance tools, the method comprising: acquiring, using an NMR sensor a first NMR signal from a volume in a subterranean region, wherein the first NMR signal is acquired using a first acquisition window; acquiring, using the NMR sensor a second NMR signal from a volume in the subterranean region, wherein the second NMR signal is acquired using a second acquisition window different from the first acquisition window, wherein the first NMR signal and the second NMR signal form an NMR relaxation data; determining, using the first NMR signal and the second NMR signal, a correction term; and using the correction term to acquire a corrected relaxation data set.

Statement 2, the method of Statement 1, wherein the first acquisition window and the second acquisition window are selected to minimize noise added by the correction term.

Statement 3, the method of Statements 2 or 3, wherein the first acquisition window corresponds to matched reception maximizing signal-to-noise ratio of the first NMR signal and the NMR relaxation data constitutes the first NMR signal.

Statement 4, the method of Statements 1-3, wherein the correction term is determined at least by a normalized relaxation data and acquired relaxation data set.

Statement 5, the method of any of Statements 1-4, wherein the correction term is determined by:

$${R}_{corr} ( t ) = R ( t , {W}_{0} ) + c \cdot {[ {R}_{na} ( t , {W}_{M} ) - R ( t , {W}_{0} ) ]}_{s} ,$$

wherein R(t, W₀) represents acquired relaxation data set and Rₙₐ (t, W_{M}) represents the normalized relaxation data.

Statement 6, the method of any of Statement 5, wherein the first acquisition window and the second acquisition window have different sizes wherein the normalized relaxation data is acquired with auxiliary acquisition window (W_{M}).

Statement 7, the method of any of Statements 1-6, further comprising reducing noise to form a corrected NMR relaxation data with at least a noise data of two NMR relaxation datasets used to calculate the correction term.

Statement 8, the method of any of Statements 1-7, wherein the corrected NMR relaxation data is:

$${N}_{corr} ( t ) = {N}_{O} ( t ) + c \cdot [ {N}_{Ms} ( t ) - {N}_{0 s} ( t ) ] ,$$

wherein N_{corr} is the noise of corrected NMR relaxation data, No is the noise of the data to be corrected for motion effect, N_{Ms} (t) and N₀ₛ (t) are the noise data of the two NMR relaxation datasets used to calculate the correction term.

Statement 9, A NMR tool for use in a wellbore in a subterranean region, the NMR tool comprising: a magnet assembly configured to produce a magnetic field in a volume in the subterranean region; an antenna assembly configured to produce an excitation in the volume, and to receive NMR signals from the volume; and an acquisition system coupled to the antenna assembly and configured to: acquire a first NMR signal using a first acquisition window having a first duration; and acquire a second NMR signal using a second acquisition window having a second duration, wherein the second duration is different than the first duration; and a processor coupled to the acquisition system and configured to: acquire using an NMR sensor a first NMR signal from a volume in the subterranean region, wherein the first NMR signal is acquired using a first acquisition window; acquire using the NMR sensor a second NMR signal from a volume in the subterranean region, wherein the second NMR signal is acquired using a second acquisition window different from the first acquisition window, wherein the first NMR signal and the second NMR signal form an NMR relaxation data; determining, using the first NMR signal and the second NMR signal, a correction term; and using the correction term to acquire a corrected relaxation data set.

Statement 10, the NMR tool of Statement 10, wherein the first acquisition window and the second acquisition window are selected to minimize noise added by the correction term.

Statement 11, the NMR tool of Statement 10, wherein the first acquisition window corresponds to matched reception maximizing signal-to-noise ratio of the first NMR signal and the NMR relaxation data constitutes the first NMR signal.

Statement 12, the NMR tool of Statements 10-11, wherein the correction term is determined at least by a normalized relaxation data and acquired relaxation data set.

Statement 13, the NMR tool of any of Statement 12, wherein the correction term is determined by:

$${R}_{corr} ( t ) = R ( t , {W}_{0} ) + c \cdot {[ {R}_{na} ( t , {W}_{M} ) - R ( t , {W}_{0} ) ]}_{s} ,$$

wherein R(t, W₀) represents acquired relaxation data set and Rₙₐ (t, W_{M}) represents the normalized relaxation data.

Statement 14, the NMR tool of any of Statement 13, wherein the normalized relaxation data is acquired with auxiliary acquisition window (W_{M}).

Statement 15, the NMR tool of any of Statements 9-15, further comprising reducing noise to form a corrected NMR relaxation data with at least a noise data of two NMR relaxation datasets used to calculate the correction term.

Statement 16, the NMR tool of any of Statement 15, wherein the corrected NMR relaxation data is:

$${N}_{corr} ( t ) = {N}_{O} ( t ) + c \cdot [ {N}_{Ms} ( t ) - {N}_{0 s} ( t ) ] ,$$

wherein N_{corr} is the noise of corrected NMR relaxation data, No is the noise of the data to be corrected for motion effect, N_Ms (t) and N₀ₛ (t) are the noise data of the two NMR relaxation datasets used to calculate the correction term.

Statement 17, A non-transitory storage medium comprising instructions, which when executed by a processor, cause the processor to perform operations comprising: acquiring using an NMR sensor a first NMR signal from a volume in a subterranean region, wherein the first NMR signal is acquired using a first acquisition window; acquiring using the NMR sensor a second NMR signal from a volume in the subterranean region, wherein the second NMR signal is acquired using a second acquisition window different from the first acquisition window, wherein the first NMR signal and the second NMR signal form an NMR relaxation data; determining, using the first NMR signal and the second NMR signal, a correction term; and using the correction term to acquire a corrected relaxation data set.

Statement 18, the non-transitory storage medium of Statement 17, wherein the first acquisition window and the second acquisition window are selected to minimize noise added by the correction term, and wherein the first acquisition window corresponds to matched reception maximizing signal-to-noise ratio of the first NMR signal and the NMR relaxation data constitutes the first NMR signal.

Statement 19 the non-transitory storage medium of Statements 17 or 18, wherein the correction term is determined at least by a normalized relaxation data and acquired relaxation data set.

Statement 20, the non-transitory storage medium Statements 17-19, further comprising reducing noise to form a corrected NMR relaxation data with at least a noise data of two NMR relaxation datasets used to calculate the correction term.

As used herein, the singular forms “a,” “an,” and “the” are intended to include the plural forms as well, unless the context clearly indicates otherwise. It will be further understood that the terms “comprise” and/or “comprising,” when used in this specification and/or in the claims, specify the presence of stated features, steps, operations, elements, and/or components, but do not preclude the presence or addition of one or more other features, steps, operations, elements, components, and/or groups thereof. In addition, the steps and components described in the above embodiments and figures are merely illustrative and do not imply that any particular step or component is a requirement of a claimed embodiment.

What is claimed is:

1. A method to perform nuclear magnetic resonance measurements, and nuclear magnetic resonance tools, the method comprising:
acquiring, using an NMR sensor a first NMR signal from a volume in a subterranean region, wherein the first NMR signal is acquired using a first acquisition window;
acquiring, using the NMR sensor a second NMR signal from a volume in the subterranean region, wherein the second NMR signal is acquired using a second acquisition window different from the first acquisition window, wherein the first NMR signal and the second NMR signal form an NMR relaxation data;
determining, using the first NMR signal and the second NMR signal, a correction term; and
using the correction term to acquire a corrected relaxation data set.

2. The method of claim 1, wherein the first acquisition window and the second acquisition window are selected to minimize noise added by the correction term.

3. The method of claim 1, wherein the first acquisition window corresponds to matched reception maximizing signal-to-noise ratio of the first NMR signal and the NMR relaxation data constitutes the first NMR signal.

4. The method of claim 1, wherein the correction term is determined at least by a normalized relaxation data and acquired relaxation data set.

5. The method of claim 4, wherein the correction term is determined by:
$${R}_{corr} ( t ) = R ( t , {W}_{0} ) + c \cdot {[ {R}_{na} ( t , {W}_{M} ) - R ( t , {W}_{0} ) ]}_{s} ,$$
wherein R(t, W₀) represents acquired relaxation data set and Rₙₐ (t, W_{M}) represents the normalized relaxation data.

6. The method of claim 5, wherein the normalized relaxation data is acquired with auxiliary acquisition window (W_{M}).

7. The method of claim 1, further comprising reducing noise to form a corrected NMR relaxation data with at least a noise data of two NMR relaxation datasets used to calculate the correction term.

8. The method of claim 1, further comprising correction term signal-to-noise ratio calculated based at least on the relaxation data set, a normalized relaxation data, and noise data of at least the NMR relaxation data for assessing significance of the lateral motion artifacts.

9. A NMR tool for use in a wellbore in a subterranean region, the NMR tool comprising:
a magnet assembly configured to produce a magnetic field in a volume in the subterranean region;
an antenna assembly configured to produce an excitation in the volume, and to receive NMR signals from the volume; and
an acquisition system coupled to the antenna assembly and configured to:
acquire a first NMR signal using a first acquisition window having a first duration; and
acquire a second NMR signal using a second acquisition window having a second duration, wherein the second duration is different than the first duration; and
a processor coupled to the acquisition system and configured to:
acquire using an NMR sensor a first NMR signal from a volume in the subterranean region, wherein the first NMR signal is acquired using a first acquisition window;
acquire using the NMR sensor a second NMR signal from a volume in the subterranean region, wherein the second NMR signal is acquired using a second acquisition window different from the first acquisition window, wherein the first NMR signal and the second NMR signal form an NMR relaxation data;
determining, using the first NMR signal and the second NMR signal, a correction term; and
using the correction term to acquire a corrected relaxation data set.

10. The NMR tool of claim 9, wherein the first acquisition window and the second acquisition window are selected to minimize noise added by the correction term.

11. The NMR tool of claim 9, wherein the first acquisition window corresponds to matched reception maximizing signal-to-noise ratio of the first NMR signal and the NMR relaxation data constitutes the first NMR signal.

12. The NMR tool of claim 9, wherein the correction term is determined at least by a normalized relaxation data and acquired relaxation data set.

13. The NMR tool of claim 12, wherein the correction term is determined by:
$${R}_{corr} ( t ) = R ( t , {W}_{0} ) + c \cdot {[ {R}_{na} ( t , {W}_{M} ) - R ( t , {W}_{0} ) ]}_{s} ,$$
wherein R(t, W₀) represents acquired relaxation data set and Rₙₐ (t, W┤M) represents the normalized relaxation data.

14. The NMR tool of claim 13, wherein the normalized relaxation data is acquired with auxiliary acquisition window (W_{M}).

15. The NMR tool of claim 9, further comprising reducing noise to form a corrected NMR relaxation data with at least a noise data of two NMR relaxation datasets used to calculate the correction term.

16. The NMR tool of claim 15, wherein the corrected NMR relaxation data is:
$${N}_{corr} ( t ) = {N}_{O} ( t ) + c \cdot [ {N}_{Ms} ( t ) - {N}_{0 s} ( t ) ] ,$$
wherein N_{corr} is the noise of corrected NMR relaxation data, No is the noise of the data to be corrected for motion effect, N_{Ms} (t) and N₀ₛ (t) are the noise data of the two NMR relaxation datasets used to calculate the correction term.

17. A non-transitory storage medium comprising instructions, which when executed by a processor, cause the processor to perform operations comprising:
acquiring using an NMR sensor a first NMR signal from a volume in a subterranean region, wherein the first NMR signal is acquired using a first acquisition window;
acquiring using the NMR sensor a second NMR signal from a volume in the subterranean region, wherein the second NMR signal is acquired using a second acquisition window different from the first acquisition window, wherein the first NMR signal and the second NMR signal form an NMR relaxation data;
determining, using the first NMR signal and the second NMR signal, a correction term; and
using the correction term to acquire a corrected relaxation data set.

18. The non-transitory storage medium comprising instructions of claim 17, wherein the first acquisition window and the second acquisition window are selected to minimize noise added by the correction term, and wherein the first acquisition window corresponds to matched reception maximizing signal-to-noise ratio of the first NMR signal and the NMR relaxation data constitutes the first NMR signal.

19. The non-transitory storage medium comprising instructions of claim 17, wherein the correction term is determined at least by a normalized relaxation data and acquired relaxation data set.

20. The non-transitory storage medium comprising instructions of claim 17, further comprising reducing noise to form a corrected NMR relaxation data with at least a noise data of two NMR relaxation datasets used to calculate the correction term.
